(19) United States
(12) Patent Application Publication
(10) Pub. No.: US 2016/0299084 A1
(43) Pub. Date: Oct. 13, 2016

(54) Systems and Methods to Reduce Delamination In Integrated Computational Elements Used Downhole

(71) Applicant: HALLIBURTON ENERGY SERVICES, INC., Houston, TX (US)

(72) Inventors: James M. Price, Spring, TX (US); David L. Perkins, The Woodlands, TX (US); Robert Atkinson, Conroe, TX (US)

(73) Assignee: HALLIBURTON ENERGY SERVICES, INC., Houston, TX (US)

(21) Appl. No.: 14/441,266

(22) PCT Filed: Dec. 18, 2013
(86) PCT No.: PCT/US2013/076227

§ 371 Date: May 7, 2015

(51) Int. Cl. G01N 21/84; G01N 23/207; E21B 49/08; C23C 14/54; C23C 16/52; G01N 21/65; G01N 21/21

(52) U.S. Cl. CPC G01N 21/8422; G01N 21/65; G01N 23/207; G01N 21/211; C23C 14/54; C23C 16/52; E21B 49/08; G01N 2021/213; G01N 2021/8438; G01V 8/10

(57) ABSTRACT

Systems and methods are disclosed for reducing delamination or cracking in a multilayer film stack fabricated on a substrate. The multilayer film stack is designed to optically process a sample fluid interacted electromagnetic radiation to measure various chemical or physical characteristics of a production fluid from a wellbore. Systems and methods measure in situ a characteristic of the multilayer film stack during fabrication and compare the measured characteristic against a reference criterion. The reference criterion has been predetermined to represent an onset of delamination or cracking. If the reference criterion is met, fabrication of the multilayer film stack is modified to reduce the possibility of delamination or cracking. Other systems and methods are presented.

### TECHNICAL FIELD

The present disclosure relates generally to the manufacture of integrated computational elements, and more particularly, but not by way of limitation, to systems and methods to reduce delamination or cracking in multilayer film stacks fabricated on substrates. The multilayer film stacks are for use with optical spectra representing a chemical constituent of a production fluid from a wellbore.

### BACKGROUND

In producing fluids from an oil and gas well, it is often advantageous to learn as much about the fluids in the well as possible. In recent times, more and more information is being developed by downhole instruments and tools. Still, additional information and improvements are desired. Integrated computational elements assist in identifying fluids or fluid characteristics.

### BRIEF DESCRIPTION OF THE DRAWINGS

FIG. 1 is a cross-sectional view of a portion of an illustrative embodiment of a multilayer film stack for transmitting an optical spectrum representing a chemical constituent of a production fluid from a wellbore;

FIG. 2 is a schematic diagram of an illustrative embodiment of a system for reducing delamination or cracking of a multilayer film stack fabricated on a substrate;

FIG. 3 is a schematic flowchart of an illustrative embodiment of a method for reducing delamination or cracking of a multilayer film stack fabricated on a substrate for use in a wellbore;

FIG. 4 is a schematic flowchart of an illustrative embodiment of a method for producing a configuration of abutted films that form a multilayer film stack; and

FIG. 5 is a schematic flowchart of an illustrative embodiment of a method for forming a film of the multilayer film stack according to a process plan.

### DETAILED DESCRIPTION OF ILLUSTRATIVE EMBODIMENTS

In the following detailed description of the illustrative embodiments, reference is made to the accompanying drawings that form a part hereof. These embodiments are described in sufficient detail to enable those skilled in the art to practice the invention, and it is understood that other embodiments may be utilized and that logical structural, mechanical, electrical, and chemical changes may be made without departing from the scope of the invention. To avoid detail not necessary to enable those skilled in the art to practice the embodiments described herein, the description may omit certain information known to those skilled in the art. The following detailed description is, therefore, not to be taken in a limiting sense, and the scope of the illustrative embodiments is defined only by the appended claims.

In the drawings and description that follow, like parts are typically marked throughout the specification and drawings with the same reference numerals or coordinated numerals. The drawing figures are not necessarily to scale. Certain features of the invention may be shown exaggerated in scale or in somewhat schematic form and some details of conventional elements may not be shown in the interest of clarity and conciseness.

Production fluids in the oil and gas field may be analyzed at times using electromagnetic radiation. In such analyses, an electromagnetic radiation is interacted with a production fluid to acquire attributes of chemical constituents therein and produce a sample interacted electromagnetic radiation. The sample interacted electromagnetic radiation may be optically processed by an integrated computational element in an optical analysis tools for analyzing a substance of interest, for example, crude petroleum, gas, water, or other wellbore fluids. The integrated computational elements enable the measurement of various chemical or physical characteristics through the use of regression techniques.

The integrated computational element can be an interference based multilayer film stack fabricated on a substrate. The multilayer film stack is operational via reflection, transmittance, or a combination thereof to weight the sample interacted electromagnetic radiation on a per-wavelength basis. The weighting process produces an integrated computational element interacted electromagnetic radiation and is used to relate to one or more characteristics of the sample. Because integrated computational elements are configured to extract information from the light modified by a sample passively without having to perform spectral analysis outside of the integrated computational elements, they can be incorporated into low cost and rugged optical analysis tools. Hence, integrated-computational-element-based downhole optical analysis tools can provide a relatively low cost, rugged and accurate system for monitoring quality of wellbore fluids.

The weighting fractions, however, are typically dependent on the number, thickness, and refractive indices of films in the multilayer film stack. Furthermore, structural flaws in the multilayer film stack, such as those generated by delamination or cracking, may significantly reduce the accuracy of a weighted optical spectrum. The present systems and methods help address (e.g., reduce or eliminate) such delamination or cracking.

The embodiments described herein relate to systems and methods for reducing delamination or cracking in a multilayer film stack fabricated on a substrate. The multilayer film stack is designed to relate to one or more characteristics of the sample, such as a production fluid from a wellbore. Systems and methods are disclosed that, during fabrication, measure in situ a characteristic of the multilayer film stack and compare the measured characteristic against a reference criterion. As used herein, “in situ” means with the substrate in a manufacturing vessel.

The reference criterion has been predetermined to represent an onset of delamination or cracking. If the reference criterion is met, fabrication of the multilayer film stack is modified or halted to address the onset of delamination and cracking. The systems and methods disclosed herein also may allow for an in situ modification to a design of the multilayer film stack. The design modification compensates for stress or strain conditions in the existing films of the multilayer film stack that might otherwise lead to delamination or cracking. Using the modified design, fabrication of the multilayer film stack can be continued and the probability of delamination or cracking substantially reduced. Other systems and methods are presented.

As used herein, the terms “delamination” and “cracking” refer to any structural flaw that emerges within a multilayer film stack in response to excessive strain, excessive stress, or a combination thereof. Structural flaws may manifest themselves during fabrication or at some time thereafter. Delamination or cracking may include mechanical failure of a film, an interface associated with a film (e.g., a film-film interface or a film-substrate interface), or both. Non-limiting examples of delamination include blistering, wrinkling, folding, spalling, or buckling. Complete detachment of a multilayer film stack, or a portion thereof, is also possible. Cracking of a multilayer film includes any void that interrupts the planar continuity of a multilayer film stack. Cracks may penetrate the multilayer film stack through any depth (e.g., a fissure) which includes propagation into the substrate. Cracking may occur concomitantly with delamination.

Unless otherwise specified, any use of any form of the terms “connect,” “engage,” “couple,” “attach,” or any other term describing an interaction between elements is not meant to limit the interaction to direct interaction between the elements and may also include indirect interaction between the elements described. In the following discussion and in the claims, the terms “including” and “comprising” are used in an open-ended fashion, and thus should be interpreted to mean “including, but not limited to”. Unless otherwise indicated, as used throughout this document, “or” does not require mutual exclusivity.

The various characteristics mentioned above, as well as other features and characteristics described in more detail below, will be readily apparent to those skilled in the art with the aid of this disclosure upon reading the following detailed description of the embodiments, and by referring to the accompanying drawings. Other means may be used as well.

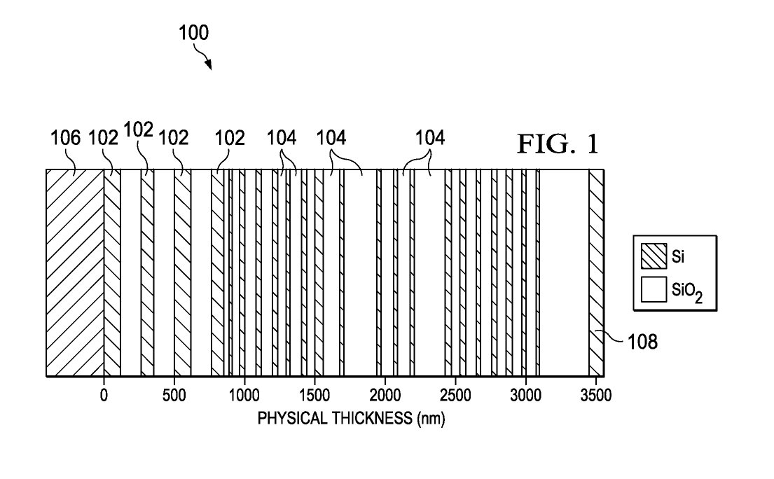

Now referring primarily to FIG. 1, a cross-sectional view is shown of a portion of an illustrative embodiment of a multilayer film stack 100 to relate to one or more characteristics of the sample, such as a production fluid from a wellbore. The multilayer film stack 100 includes alternating layers 102 of high refractive index and layers 104 of low refractive index. In the embodiment illustrated by FIG. 1, the layers of high refractive index 102 are formed of silicon and those of low refractive index 104, silicon dioxide. This embodiment, however, is not intended as limiting. The layers 102 may be formed of other materials that have a high refractive index. Non-limiting examples of such materials include germanium, aluminum arsenide, gallium arsenide, indium phosphide, silicon carbide, and Titanium oxide (TiO2). Similarly, the layers 104 may be formed of other materials that have a low refractive index. Non-limiting examples of these materials include germanium dioxide, magnesium fluoride, and aluminum oxide.

The multilayer film stack 100 is fabricated on a substrate 106 to provide support for the layers 102, 104. The substrate 106 may be a single crystal, a polycrystalline ceramic, an amorphous glass, a plastic material, or other suitable material. In some embodiments, the substrate 106 is formed of BK-7 optical glass. The substrate may be optically transparent in some embodiments. In some embodiments, the substrate 106 may be quartz, diamond, sapphire, silicon, germanium, magnesium fluoride, aluminum nitride, gallium nitride, zinc selenide, zinc sulfide, fused silica, polycarbonate, polymethylmethacrylate (PMMA), or polyvinylchloride (PVC). In one illustrative embodiment, the substrate is formed from a BK7 glass sample whose backside has been frosted such that light is reflected back. Other substrates are possible. In some embodiments, the multilayer film stack 100 includes an optional capping layer 108 that, during operation, is exposed to the target production fluid.

The multilayer film stack 100, the substrate 106, and the capping layer 108 (if present) function in combination as an integrated computational element. The integrated computational unit optically processes an electromagnetic radiation according to a spectral weighting (i.e., a wavelength-dependent weighting). In operation, the electromagnetic radiation enters the integrated computational element and interacts with the layers 102, 104 of the multilayer film stack 100. The layers 102, 104 induce reflection, refraction, interference, or a combination thereof within the multilayer film stack 100 to alter an intensity of the electromagnetic radiation on a per-wavelength basis. The electromagnetic radiation exits the integrated computational unit as a weighted optical spectrum whose individual wavelengths have been proportionately filtered by the multilayer film stack 100. While light may enter either side, light is discussed here as entering the integrated computational element from the substrate-side.

The spectral weighting is controlled by selection of substrate and by varying one or more of a thickness, a refractive index, and a number of individual layers 102, 104 of the multilayer film stack 100. The substrate, thickness, the refractive index (i.e., material), and the number of layers may be selected according to a design of the multilayer film stack 100 to produce an optical spectrum that is related to one or more characteristics of the sample. During analysis of the production fluid, electromagnetic radiation is passed through or off the production fluid and delivered to an integrated computational element incorporating the design. Interaction of the electromagnetic radiation with the production fluid allows the electromagnetic radiation to acquire optical characteristics that represent attributes of the production fluid and produces sample interacted light. Subsequent optical processing by the integrated computational element produces an integrated-computational-element-interacted light. The integrated-computational-element-interacted light is then sent to an analysis unit to determine desired information about the sample, such as chemical constituent (e.g., concentration).

It should be understood that the design shown in FIG. 1 does not necessarily correspond to any particular chemical constituent, but is provided for purposes of general illustration only. Furthermore, the layers 102, 104 and their relative thicknesses are not necessarily drawn to scale, and should not be considered limiting of the present disclosure.

Deviations in thickness, refractive index, and number from that specified in the design will degrade the weighting desired from the integrated computational element. As a result, the accuracy of information obtained from any weighted optical spectrum is reduced. Such reductions in accuracy become unacceptable if the layers 102, 104 or the entire multilayer film stack 100 exhibit structural flaws such as those produced by delamination or cracking. Delamination or cracking occurs when the layers 102, 104 lower stress or strain values associated with compressive or tensile conditions within the multilayer film stack 100. Compressive or tensile conditions are a by-product of atomic lattice mismatch between adjacent layers of differing materials (e.g., Si and SiO2). Compressive or tensile conditions, however, may also be exacerbated by the presence of overlying layers which tend to increase the compressive or tensile magnitudes experienced by underlying layers. It has been empirically observed that the probability of delamination or cracking in a multilayer film stack 100 rises substantially if an individual layer thickness exceeds approximately 1300 nm, a combined layer thickness exceeds approximately 6000 nm, or both. However, such observations are not reliable in predicting the onset of delamination or cracking. Thus, fabrication of an integrated computational element may be improved by monitoring in situ characteristics of the multilayer film stack 100 during fabrication that represent stress or stain values of the individual layers 102, 104 or the multilayer film stack 100.

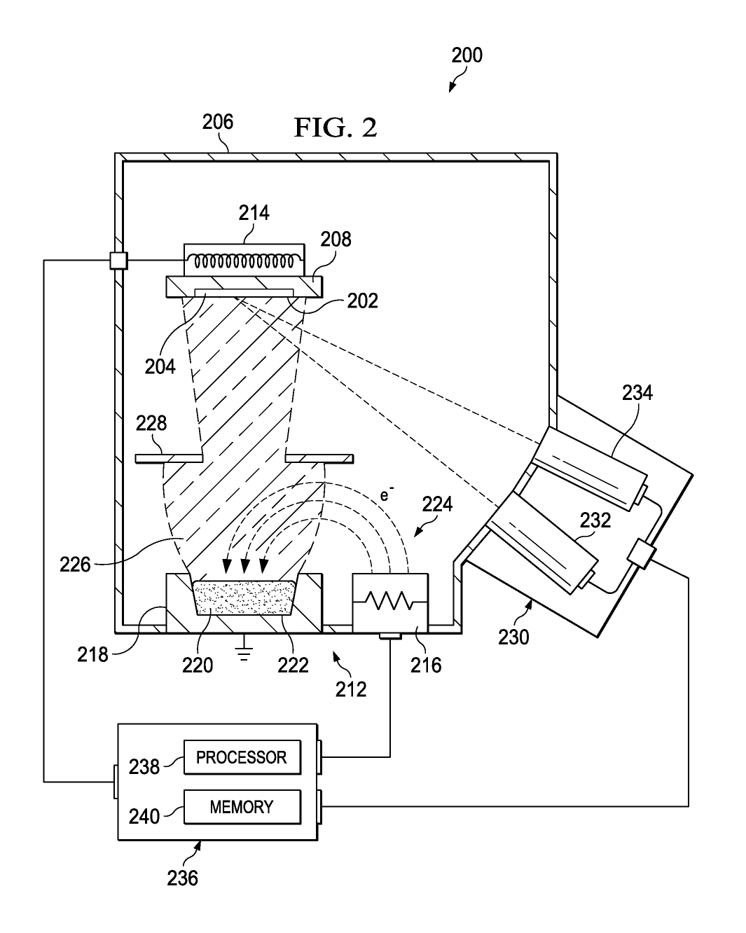

Now referring primarily to FIG. 2, a schematic diagram of an illustrative embodiment of a system 200 for reducing delamination or cracking of a multilayer film stack 202 fabricated on a substrate 204 is presented. The multilayer film stack 202 is fabricated to optically process a sample interacted electromagnetic radiation to measure various chemical or physical characteristics as previously discussed. The system 200 includes a chamber 206 and a substrate holder 208. The substrate holder 208 secures the substrate 204 within the chamber 206 relative to a mass-flux generator 212. The substrate holder 208 may include an optional heater 214 for raising and maintaining a temperature of the substrate 204 above ambient. The optional heater 214 in some embodiments may not be coupled to the substrate 204 as such. For example, in one embodiment heating lamps, e.g., halogen lamps, inside the chamber 206 are used to uniformly heat the entire chamber 206 and substrate 204 to a desired temperature. The mass-flux generator 212 is coupled to the chamber 206 and includes an electron gun 216 and a crucible 218 for heating a mass source 220. The mass source 220 is contained within a pocket 222 of the crucible 218 and sits adjacent the electron gun 216.

The electron gun 216 is operable to generate a beam of electrons 224 from a filament and arc the beam of electrons 224 into the pocket 222 of the crucible 218 via a magnetic field. Energy from the beam of electrons 224 is absorbed by the mass source 220 producing heat which induces evaporation. A water-cooling circuit (not shown) is typically incorporated into the crucible 218 to prevent the crucible 218 from decomposing or melting. The crucible 218 is electrically grounded. Evaporation of the mass source 220 is operable to generate a mass flux 226 which is received by the substrate holder 208. The mass-flux generator 212 may include a collimator 228 to focus the mass flux 226 onto the substrate 204. The mass flux 226 may include elements, molecules, or a combination thereof. Impingement of the mass flux 226 onto the substrate 204, or onto existing films already formed on the substrate 204, allows the system 200 to form a film of the multilayer film stack 202.

In some embodiments, the crucible 218 contains two or more pockets 222 for holding two or more different mass sources 220 (e.g., Si and SiO2). The electron gun 216 arcs the beam of electrons 224 into the appropriate pocket 222 to heat the desired mass source 220. This configuration may allow the system 200 to fabricate a multilayer film stack 202 completely without exposing the chamber 206 to an ambient environment (i.e., to introduce a new mass source 220). In other embodiments, the system 200 may include an ion-beam generator (not shown) to allow films to be formed using ion-assisted electron beam evaporation. The use of an ion-beam generator during film deposition may help reduce porosity (i.e., densify) in the final, formed film.

Further coupled to the chamber 206 is a precision measurement device 230. The precision measurement device 230 is oriented towards the substrate 204 and is configured to measure in situ a materials characteristic of the multilayer film stack 202 during fabrication. The precision measurement device 230 may include a probe 232 and a detector 234. The probe 232 emits an electromagnetic radiation to interact with the multilayer film stack 202. The detector 234 analyzes the interacted electromagnetic radiation to generate a signal representing the materials characteristic of the multilayer film stack 202. While not explicitly shown, in some embodiments, the probe 232 and detector 234 are on opposing sides of the chamber 206 and at the same angle of incidence.

Coupled to the mass-flux generator 212 and the precision measurement device 230 is a computational unit 236. The computational unit 236 includes one or more processors 238 and one or more memories 240 to control film formation during fabrication of the multilayer film stack 202. The computational unit 236 may be further coupled to the heater 214, if present, to manipulate the temperature of the substrate 204 during fabrication. The computational unit 236 may also control measurement of the materials characteristic. During a measurement process, the computational unit 236 receives the signal from the detector 234. The one or more processors 238 and one or more memories 240 are operable to determine the measured materials characteristic from the signal. The computational unit 236 is further operational to evaluate the measured materials characteristic against a reference criterion.

In operation, the chamber 206 is evacuated and the electron beam 224 emanated from the electron gun 216. The electron beam 224 is directed into the pocket 222 of the crucible 218 by the magnetic field. Evaporation of the mass source 220 produces the mass flux 226 which traverses a distance from the crucible 218 to the substrate holder 208. To improve focus of the mass flux 226 onto the substrate 204, the mass-flux generator 212 may include the collimator 228. The mass-flux generator 212 directs the mass-flux 226 towards the substrate 204 to form a film of the multilayer film stack 202. An ion gun may also be used.

The formation process is controlled by the computational unit 236. When the film has achieved its desired, predetermined thickness, the mass-flux generator 212 is deactivated by the computational unit 236. The heater 210, if present, may be functional during the formation process in order to improve film properties such as density and microstructure. The computational unit 236 regulates the mass-flux generator 212 to form a series of sequential films. A number, thickness, and refractive index (i.e., material) of sequential films in the series is specified by a design of the multilayer film stack 202. The design of the multilayer film stack 202, when executed to completion, produces alternating layers of high refractive index 102 and low refractive index 104 as illustrated in the multilayer film stack 100 of FIG. 1. The capping layer 108 may also be present. At times, one or more layers may, for a number of reasons, be formed with a thickness or other characteristics (e.g., composition, stoichiometry, or crystal structure) different than desired and monitoring is desired.

During fabrication of the multilayer film stack 202, the computational unit 236 also controls the precision measurement device 230. The precision measurement device 230 is operational to measure in situ the materials characteristic of the multilayer film stack 202. Such measurement may occur while the film is being formed or during a time period thereafter. The measurement may be continuous or intermittent. To measure the materials characteristic, the probe 232 of the precision measurement device 230 emits electromagnetic radiation towards the substrate 204 in order to interact electromagnetic radiation with the multilayer film stack 202. The detector 234 of the precision measurement device 230 then analyzes electromagnetic radiation leaving the substrate 204 to produce a signal that represents the materials characteristic. The signal is received by the computational unit 236, which determines the materials characteristic using the one or more processors 238 and one or more memories 240.

The computational unit 236 further evaluates the materials characteristic against a reference criterion. The reference criterion has been predetermined to represent an onset of delamination or cracking. In some embodiments, the computational unit 236 determines a stress parameter, a strain parameter, or a combination thereof using the measured materials characteristic. In such embodiments, the reference criterion includes a threshold value for the stress parameter, the strain parameter, or the combination thereof. The computational unit 232 compares the determined parameters against respective threshold values to determine when action is desired to reduce a probability of delamination or cracking in the multilayer film stack 202 during fabrication. In other embodiments, the computational unit 232 evaluates the measured materials characteristic against the reference criterion, but without determining a strain or stress parameter of the multilayer film stack 202. The reference criterion includes values of the measured materials characteristic which correlate to an onset of delamination or cracking. Such correlations are typically predetermined through independent experimentation.

If the reference criterion is met, the computational unit 236 stops fabrication of the multilayer film stack 202. The design of the multilayer film stack 202 is then modified to compensate for compressive or tensile conditions which exist in the multilayer film stack 202. In some embodiments, modification of the design is completed by the computational unit 236 according to a program stored in the one or more memories 240 and executed by the one or more processors 238. In other embodiments, modification of the design is completed independently by one or more individuals skilled in the art. After modification, the computational unit 236 then continues fabrication of the multilayer film stack 202 according to the modified design.

The system 200 illustrated in FIG. 2 has been presented in the context of an electron beam deposition system. This illustration, however, is not intended to be limiting. The integrated computation elements presented herein may be fabricated using systems that employ other deposition techniques such as thermal evaporation, dc-sputtering, dc-magnetron sputtering, rf-sputtering, reactive physical vapor deposition (RPVD), ionized physical vapor deposition (IPVD), pulsed laser deposition (PLD), low pressure chemical vapor deposition (LPCVD), plasma-enhanced chemical vapor deposition (PECVD), atomic layer deposition (ALD), atmospheric pressure chemical vapor deposition (APCVD), metal organic chemical deposition (MOCVD), and molecular beam epitaxy (MBE). Other deposition techniques are possible.

Furthermore, the precision measurement device 230 is depicted in FIG. 2 to include a probe 232 and a detector 234. Such a configuration is consistent with a Raman spectrometer, which includes a laser and a charge-coupled device (CCD) for, respectively, the probe 232 and the detector 234. In this embodiment, the precision measurement device 230 measures a phonon resonance of the multilayer film stack 202. For example, if the multilayer film stack 202 contains films of elemental silicon, a Si—Si phonon resonance may be measured by monitoring a Raman intensity peak near 521 cm-1. Compressive and tensile conditions emerging within the multilayer film stack 202 during fabrication may shift the Raman intensity peak away from its expected wavenumber of 521 cm-1. However, the depiction in FIG. 2 is not intended to be limiting. Other configurations are possible to measure the same or different materials characteristics. The precision measurement device 230 may include a photoreflectance spectrometer to measure the direct band gap; an ellipsometer to measure a band gap or a shift in optical properties; a second harmonic generation spectrometer to measure a second order susceptibility; an X-ray diffractometer to measure a lattice constant; a surface acoustic wave spectrometer to measure a Young's modulus; an optical reflectometer to measure a bowing of the multilayer film stack 202, the substrate 204, or both; or a contact profilometer to measure a curvature of the multilayer film stack 202, the substrate 204, or both. Electro-reflectance and thermo-reflectance methods apply under the same principles. Other precision measurement devices 230 are possible. In some embodiments, two or more precision measurement devices 230 may be used collectively to reduce delamination or cracking of the multilayer film stack 202.

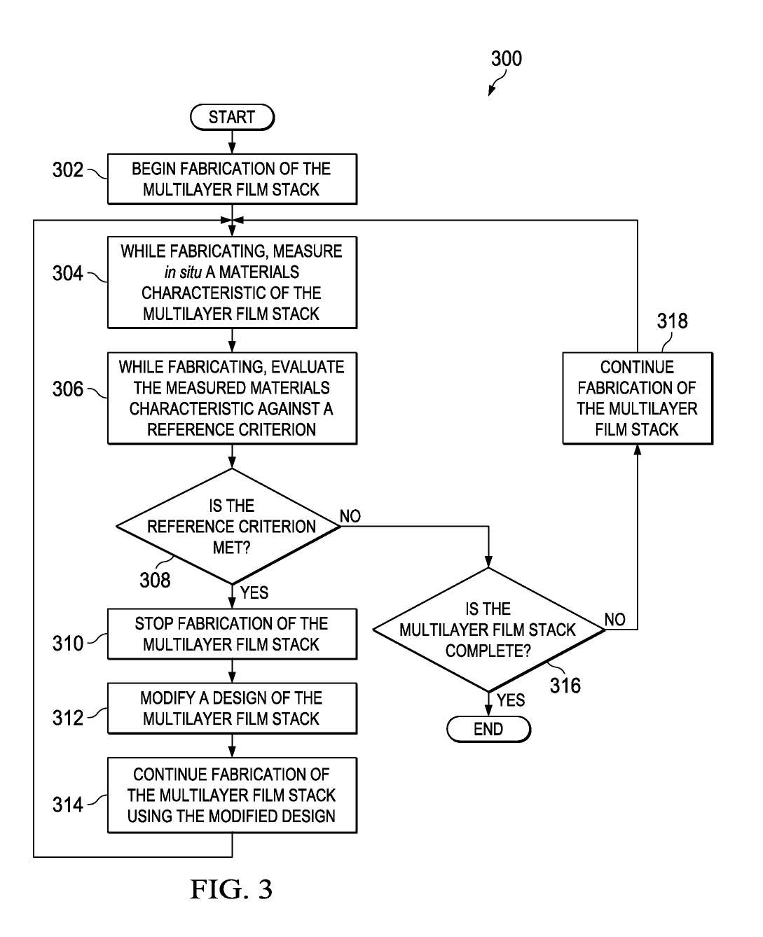

Now referring primarily to FIG. 3, a schematic flowchart of an illustrative embodiment of a method 300 for reducing delamination or cracking of a multilayer film stack fabricated on an substrate for use in a wellbore is presented. The multilayer film stack is fabricated to transmit an optical spectrum representing a chemical constituent of a production fluid from the wellbore. The method 300 includes the step 302 of beginning fabrication of the multilayer film stack. The method 300 includes the step 304 of measuring a materials characteristic of the multilayer film stack in situ during fabrication with a precision measurement device and the step 306 of evaluating the measured materials characteristic against a reference criterion during fabrication. The evaluation of the measured materials characteristic may include a decision, represented by interrogatory 308, to determine whether the reference criterion is met. If the reference criterion is met, the method 300 includes the step 310 of modifying, including stopping or adjusting, fabrication of the multilayer film stack. In some embodiments, the method 300 may further include the step 312 of modifying a design of the multilayer film stack if the reference criterion is met. In such embodiments, the method 300 then proceeds to step 314 of continuing fabrication of the multilayer film stack using the modified design. As shown in FIG. 3, step 314 may return the method 300 to step 304 so that the materials characteristic is measured in situ as the fabrication continues.

If the reference criterion is not met, the method 300 may involve a decision, illustrated by interrogatory 316, to determine whether the multilayer film stack is completely fabricated. If the multilayer film stack is finished, the method 300 ends. If the multilayer film stack is not finished, the method 300 proceeds to step 318 of continuing fabrication of the multilayer film stack. As shown in FIG. 3, step 318 returns the method 300 to step 304 so that the materials characteristic is measured in situ as the fabrication continues. In some embodiments, steps 304-318 of the method 300 are repeated as necessary until the multilayer film stack is completely fabricated.

In some embodiments, the step 306 of evaluating the measured materials characteristic against the reference criterion includes correlating the measured materials characteristic to one or both of a stress parameter and a strain parameter of the multilayer film stack. In such embodiments, the reference criterion includes a threshold value for one or both of the strain parameter and the stress parameter. Thus, after correlation, the step 306 also includes comparing one or both of the strain parameter and the stress parameter to respective threshold values.

The step 304 of measuring the materials characteristic in situ may involve one or more techniques known by those skilled in the art. Non-limiting examples of a specific materials characteristic and its associated measurement technique include a phonon resonance measured using Raman spectroscopy; a direct band gap measured using modulation spectroscopy (i.e., photo-reflectance, electro-reflectance, or thermal-reflectance); a direct band gap or optical properties measured using spectroscopic ellipsometry; a second-order susceptibility measured using second harmonic generation; a lattice spacing measured using X-ray diffraction; a Young's modulus measured using a surface acoustic wave spectroscopy; a bowing of the multilayer film stack, the substrate, or both measured using an optical reflectomotery; and a curvature of the multilayer film stack, the substrate, or both measured using contact profilometry. Other materials characteristics and associated measurement techniques are possible.

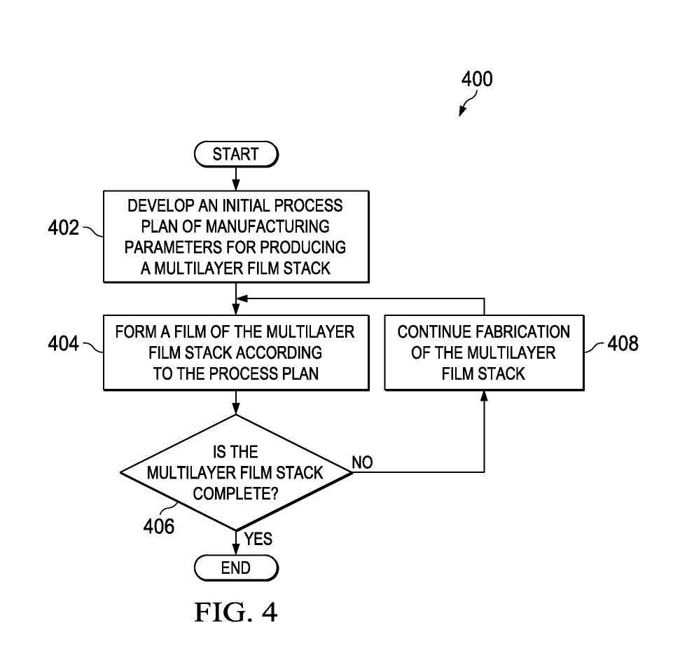

Now referring primarily to FIG. 4, a schematic flowchart of an illustrative embodiment of a method 400 for producing a configuration of abutted films that form a multilayer film stack is presented. The configuration allows the multilayer film stack to transmit an optical spectrum representing a chemical constituent of a production fluid from a wellbore. The optical spectrum is operative to enable the multilayer film stack to determine characteristics of the production fluid. The method 400 includes the step 402 of developing an initial process plan of manufacturing parameters for producing the multilayer film stack. The initial process plan is derived from a design of the multilayer film stack and includes manufacturing parameters for fabrication. Such manufacturing parameters may be used by the system 200 illustrated in FIG. 2 during fabrication of the multilayer film stack 202. Non-limiting examples of manufacturing parameters include a substrate temperature, a mass source temperature, a deposition rate, a deposition time, a substrate rotation rate, a working distance (i.e., a distance between the substrate and mass-flux generator), a chamber vacuum level, a process gas flow rate, and a process gas pressure. Other manufacturing parameters are possible. The method 400 also includes the step 404 of forming a film of the multilayer film stack according the initial process plan. The method 400 involves a decision, represented by interrogatory 406, to determine if the multilayer film stack is completely fabricated. If the multilayer film stack has been completed, the method 400 ends. If it has not, the method proceeds to step 408 of continuing fabrication of the multilayer film stack. In FIG. 4, steps 404-408 are shown to loop iteratively until the multilayer film stack is completed.

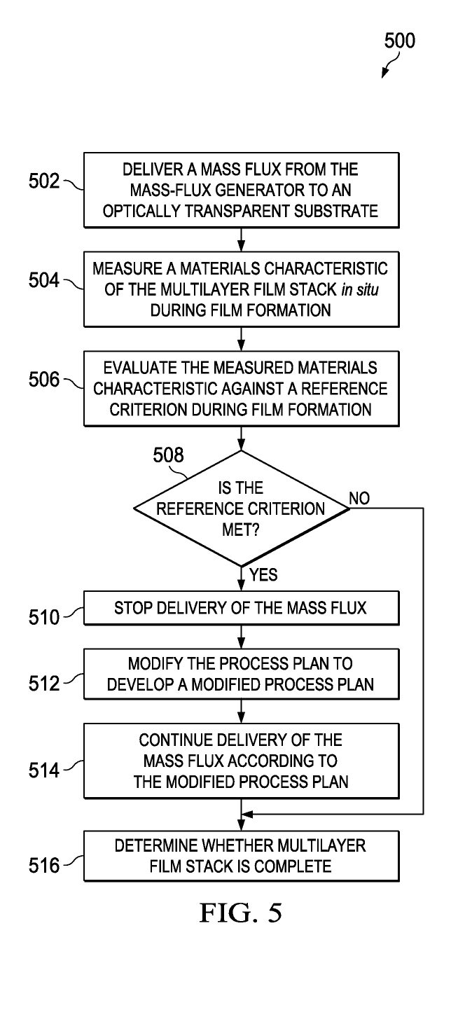

Now referring primarily to FIG. 5, but also to FIG. 4, a schematic flowchart of an illustrated embodiment of a method 500 for forming a film of the multilayer film stack according to a process plan is presented. The method 500 in FIG. 5 corresponds to an illustrative breakdown of the step 404 shown in FIG. 4. The method 500 includes the step 502 of delivering a mass flux from a mass-flux generator to a substrate. The method 500 also includes the step 504 of measuring a materials characteristic of the multilayer film stack in situ during film formation with a precision measurement device and the step 506 of evaluating the measured materials characteristic against a reference criterion during film formation. The evaluation of the measured materials characteristic may include a decision, represented by interrogatory 508, to determine whether the reference criterion is met. If the reference criterion is met, the method 500 includes the step 510 of modifying or stopping delivery of the mass flux. The method 500 then also involves the step 512 of modifying the initial process plan to develop a modified process plan to address the apparent variation in results in the multilayer film to reduce the possibility of delamination or cracking. Because the process plan is derived from a design of the multilayer film stack, modifications of the process plan occur in response to modifications of the design. Manufacturing parameters may be added, removed, or altered in order to modify the process plan. The method 500 also includes the step 514 of continuing delivery of the mass flux according to the modified process plan. As shown in FIG. 5, step 514 is followed by step 516 of determining whether the multilayer film stack is complete. If the reference criterion is not met, the method 500 also proceeds to step 516. Step 516 in FIG. 5 corresponds to the decision represented by interrogatory 406 in FIG. 4.

In addition to the embodiments described above, many examples of specific combinations are within the scope of the disclosure, some of which are detailed below.

### Example 1

A method for reducing delamination or cracking of a multilayer film stack fabricated on a substrate for use in measuring the properties of a sample fluid, the method comprising:
measuring a materials characteristic of the multilayer film stack in situ during fabrication with a precision measurement device;
evaluating the measured materials characteristic against a reference criterion during fabrication;
modifying fabrication of the multilayer film stack if the reference criterion is met; and wherein the multilayer film stack is fabricated to transmit an optical spectrum related to one or more characteristics of the sample fluid.

### Example 2

The method of Example 1, the method further comprising:
modifying a design of the multilayer film stack if the reference criteria is met; and
continuing fabrication of the multilayer film stack using the modified design.

### Example 3

The method of Example 2, the method further comprising repeating the steps of measuring the materials characteristic, evaluating the measured materials characteristic, modifying fabrication, modifying the design, and continuing fabrication until the multilayer film stack is completely fabricated.

### Example 4

The method of Example 1 or any of Examples 2-3, wherein evaluating the measured materials characteristic against a reference criterion comprises:
correlating the measured materials characteristic to one or both of a strain parameter and a stress parameter of the multilayer film stack; and
comparing one or both of the strain parameter and the stress parameter to respective threshold values.

### Example 5

The method of Example 1 or any of Examples 2-4, wherein measuring a characteristic of the multilayer film stack during fabrication comprises measuring a phonon resonance during fabrication using Raman spectroscopy.

### Example 6

The method of Example 1 or any of Examples 2-4, wherein measuring a characteristic of the multilayer film stack during fabrication comprises measuring the direct band gap during fabrication using modulation spectroscopic methods.

### Example 7

The method of Example 1 or any of Examples 2-4, wherein measuring a characteristic of the multilayer film stack during fabrication comprises measuring the direct band gap or optical properties during fabrication using spectroscopic ellipsometry.

### Example 8

The method of Example 1 or any of Examples 2-4, wherein measuring a characteristic of the multilayer film stack during fabrication comprises measuring a second-order susceptibility during fabrication using second harmonic generation.

### Example 9

The method of Example 1 or any of Examples 2-4, wherein measuring a characteristic of the multilayer film stack during fabrication comprises measuring a lattice spacing of the multilayer film during fabrication using X-ray diffraction.

### Example 10

A system for reducing delamination or cracking of a multilayer film stack fabricated on a substrate to transmit an optical spectrum representing a chemical constituent of a production fluid from a wellbore, the system comprising:
a chamber;
a mass-flux generator associated with the chamber and configured to direct a mass flux of elements, molecules, or combination thereof within the chamber towards the substrate, the mass flux operable to form a film of the multilayer film stack;
a precision measurement device configured to measure a materials characteristic of the multilayer film stack during fabrication, the precision measurement device associated with the chamber for in situ measurement of the materials characteristic;
a computational unit coupled to the mass-flux generator to control film formation during fabrication of the multilayer film stack and further coupled to the precision measurement device to control measurement of the materials characteristic and receive the measured materials characteristic; and wherein the computational unit comprises one or more processors and one or more memories, the one or more processors and one or more memories configured to evaluate the measured materials characteristic against a reference criterion and modify a process plan to address a deviation in one or more films.
Example 11

The system of Example 10, wherein the reference criterion comprises a threshold value for a stress parameter, a strain parameter, or a combination thereof.

### Example 12

The system of Example 10 or Example 11, wherein the precision measurement device comprises a Raman spectrometer and the measured materials characteristic comprises a phonon resonance.

### Example 13

The system of Example 10 or Example 11, wherein the precision measurement device comprises a modulation spectrometer and the measured materials characteristic comprises a direct band gap.

### Example 14

The system of Example 10 or Example 11, wherein the precision measurement device comprises an ellipsometer and the measured materials characteristic comprises a direct band gap or optical properties.

### Example 15

The system of Example 10 or Example 11, wherein the precision measurement device comprises a second harmonic generation spectrometer and the measured materials characteristic comprises a second order susceptibility.

### Example 16

The system of Example 10 or Example 11, wherein the precision measurement device comprises an X-ray diffractometer and the measured materials characteristic comprises a lattice constant.

### Example 17

The system of Example 10 or Example 11, wherein the precision measurement device comprises a surface acoustic wave spectrometer and the measured materials characteristic comprises a Young's modulus.

### Example 18

The system of Example 10 or Example 11, wherein the precision measurement device comprises an optical reflectometer and the measured materials characteristic comprises a bowing.

### Example 19

The system of Example 10 or Example 11, wherein the precision measurement device comprises a contact profilometer and the measured materials characteristic comprises a curvature.

### Example 20

A method of manufacturing a multilayer film stack for use in determining characteristics of a production fluid from a wellbore, the method for producing a configuration of abutted films that form the multilayer film stack, the configuration allowing the multilayer film stack to transmit an optical spectrum representing a chemical constituent of the production fluid, the method comprising:
developing an initial process plan of manufacturing parameters for producing the multilayer film stack;
forming a film of the multilayer film stack according to the initial process plan, the step of forming a film comprising:
   delivering a mass flux from a mass-flux generator to a substrate,
   measuring a materials characteristic of the multilayer film stack in situ during film formation with a precision measurement device,
   evaluating the measured materials characteristic against a reference criterion during film formation, and
   if the reference criterion is met, modifying the process plan to develop a modified process plan, and continuing delivery of the mass flux according to the modified process plan; and
sequentially forming films of the multilayer film stack until the multilayer film stack is completed.

### Example 21

A method for reducing delamination or cracking of a multilayer film stack fabricated on a substrate for use in measuring the properties of production fluid, the method comprising: measuring a materials characteristic of the multilayer film stack in situ during fabrication with a precision measurement device; evaluating the measured materials characteristic against a reference criterion during fabrication; modifying fabrication of the multilayer film stack if the reference criterion is met; and wherein the multilayer film stack is fabricated to transmit an optical spectrum related to one or more characteristics of the sample fluid.

Systems and methods are disclosed for reducing delamination or cracking in a multilayer film stack fabricated on a substrate. The multilayer film stack is designed to optically process a sample fluid interacted electromagnetic radiation to measure various chemical or physical characteristics of a production fluid from a wellbore. Systems and methods measure in situ a characteristic of the multilayer film stack during fabrication and compare the measured characteristic against a reference criterion. The reference criterion has been predetermined to represent an onset of delamination or cracking. If the reference criterion is met, fabrication of the multilayer film stack is modified to reduce the possibility of delamination or cracking. Other systems and methods are presented.

Although the present invention and its advantages have been disclosed in the context of certain illustrative, non-limiting embodiments, it should be understood that various changes, substitutions, permutations, and alterations can be made without departing from the scope of the invention as defined by the appended claims. It will be appreciated that any feature that is described in connection to any one embodiment may also be applicable to any other embodiment. As a non-limiting example, the process of FIG. 3 may be combined with the process of FIG. 4.

It will be understood that the benefits and advantages described above may relate to one embodiment or may relate to several embodiments. It will further be understood that reference to “an” item refers to one or more of those items.

The steps of the methods described herein may be carried out in any suitable order or simultaneous where appropriate. Where appropriate, aspects of any of the examples described above may be combined with aspects of any of the other examples described to form further examples having comparable or different properties and addressing the same or different problems.

It will be understood that the above description of the embodiments is given by way of example only and that various modifications may be made by those skilled in the art. The above specification, examples, and data provide a complete description of the structure and use of exemplary embodiments of the invention. Although various embodiments of the invention have been described above with a certain degree of particularity, or with reference to one or more individual embodiments, those skilled in the art could make numerous alterations to the disclosed embodiments without departing from the scope of the claims.

We claim:

1. A method for reducing delamination or cracking of a multilayer film stack fabricated on a substrate for use in measuring the properties of a sample fluid, the method comprising:
measuring a materials characteristic of the multilayer film stack in situ during fabrication with a precision measurement device;
evaluating the measured materials characteristic against a reference criterion during fabrication;
modifying fabrication of the multilayer film stack if the reference criterion is met; and
wherein the multilayer film stack is fabricated to transmit an optical spectrum related to one or more characteristics of the sample fluid.

2. The method of claim 1, the method further comprising:
modifying a design of the multilayer film stack if the reference criteria is met; and
continuing fabrication of the multilayer film stack using the modified design.

3. The method of claim 2, the method further comprising:
repeating the steps of measuring the materials characteristic, evaluating the measured materials characteristic, modifying fabrication, modifying the design, and continuing fabrication until the multilayer film stack is completely fabricated.

4. The method of claim 1 or any of claims 2-3, wherein evaluating the measured materials characteristic against a reference criterion comprises:
correlating the measured materials characteristic to one or both of a strain parameter and a stress parameter of the multilayer film stack; and
comparing one or both of the strain parameter and the stress parameter to respective threshold values.

5. The method of claim 1 or any of claims 2-4, wherein measuring a characteristic of the multilayer film stack during fabrication comprises measuring a phonon resonance during fabrication using Raman spectroscopy.

6. The method of claim 1 or any of claims 2-4, wherein measuring a characteristic of the multilayer film stack during fabrication comprises measuring the direct band gap during fabrication using modulation spectroscopic methods.

7. The method of claim 1 or any of claims 2-4, wherein measuring a characteristic of the multilayer film stack during fabrication comprises measuring the direct band gap or optical properties during fabrication using spectroscopic ellipsometry.

8. The method of claim 1 or any of claims 2-4, wherein measuring a characteristic of the multilayer film stack during fabrication comprises measuring a second-order susceptibility during fabrication using second harmonic generation.

9. The method of claim 1 or any of claims 2-4, wherein measuring a characteristic of the multilayer film stack during fabrication comprises measuring a lattice spacing of the multilayer film during fabrication using X-ray diffraction.

10. A system for reducing delamination or cracking of a multilayer film stack fabricated on a substrate to transmit an optical spectrum representing a chemical constituent of a production fluid from a wellbore, the system comprising:
a chamber;
a mass-flux generator associated with the chamber and configured to direct a mass flux of elements, molecules, or combination thereof within the chamber towards the substrate, the mass flux operable to form a film of the multilayer film stack;
a precision measurement device configured to measure a materials characteristic of the multilayer film stack during fabrication, the precision measurement device associated with the chamber for in situ measurement of the materials characteristic;
a computational unit coupled to the mass-flux generator to control film formation during fabrication of the multilayer film stack and further coupled to the precision measurement device to control measurement of the materials characteristic and receive the measured materials characteristic; and
wherein the computational unit comprises one or more processors and one or more memories, the one or more processors and one or more memories configured to evaluate the measured materials characteristic against a reference criterion and modify a process plan to address a deviation in one or more films.

11. The system of claim 10, wherein the reference criterion comprises a threshold value for a stress parameter, a strain parameter, or a combination thereof.

12. The system of claim 10 or claim 11, wherein the precision measurement device comprises a Raman spectrometer and the measured materials characteristic comprises a phonon resonance.

13. The system of claim 10 or claim 11, wherein the precision measurement device comprises a modulation spectrometer and the measured materials characteristic comprises a direct band gap.

14. The system of claim 10 or claim 11, wherein the precision measurement device comprises an ellipsometer and the measured materials characteristic comprises a direct band gap or optical properties.

15. The system of claim 10 or claim 11, wherein the precision measurement device comprises a second harmonic generation spectrometer and the measured materials characteristic comprises a second order susceptibility.

16. The system of claim 10 or claim 11, wherein the precision measurement device comprises an X-ray diffractometer and the measured materials characteristic comprises a lattice constant.

17. The system of claim 10 or claim 11, wherein the precision measurement device comprises a surface acoustic wave spectrometer and the measured materials characteristic comprises a Young's modulus.

18. The system of claim 10 or claim 11, wherein the precision measurement device comprises an optical reflectometer and the measured materials characteristic comprises a bowing.

19. The system of claim 10 or claim 11, wherein the precision measurement device comprises a contact profilometer and the measured materials characteristic comprises a curvature.

20. A method of manufacturing a multilayer film stack for use in determining characteristics of a production fluid from a wellbore, the method for producing a configuration of abutted films that form the multilayer film stack, the configuration allowing the multilayer film stack to transmit an optical spectrum representing a chemical constituent of the production fluid, the method comprising:
developing an initial process plan of manufacturing parameters for producing the multilayer film stack;
forming a film of the multilayer film stack according to the initial process plan, the step of forming a film comprising:
delivering a mass flux from a mass-flux generator to a substrate,
measuring a materials characteristic of the multilayer film stack in situ during film formation with a precision measurement device,
evaluating the measured materials characteristic against a reference criterion during film formation, and
if the reference criterion is met, modifying the process plan to develop a modified process plan, and continuing delivery of the mass flux according to the modified process plan; and
sequentially forming films of the multilayer film stack until the multilayer film stack is completed.
